(19) United States
(12) Patent Application Publication
(10) Pub. No.: US 2025/0364331 A1
(43) Pub. Date: Nov. 27, 2025

(54) METHOD FOR PROCESSING A WAFER AND METHOD FOR MANUFACTURING CHIPS

(71) Applicant: DISCO CORPORATION, Tokyo (JP)

(72) Inventor: Sheila HU, Tokyo (JP)

(73) Assignee: DISCO CORPORATION, Tokyo (JP)

(21) Appl. No.: 19/211,846

(22) Filed: May 19, 2025

(30) Foreign Application Priority Data
May 24, 2024 (JP) 2024-084597

(51) Int. Cl. H01L 21/77; B23K 26/364; B23K 101/40

(52) U.S. Cl. CPC H01L 21/77; B23K 26/364; B23K 2101/40

(57) ABSTRACT

A method for processing a wafer to form a processing groove on the wafer along a predetermined dividing line, on at least a part of which a structure is formed, comprises forming a first processing groove by removing the structure partly and leaving at least an end portion of the structure, which includes at least one end of the structure in a widthwise direction of the predetermined dividing line, and forming a second processing groove along the predetermined dividing line by removing the end portion of the structure being left in forming the first processing groove.

### CROSS REFERENCE TO RELATED APPLICATION

This application is based upon and claims the benefit of priority from the prior Japanese Patent Application No. 2024-084597 filed on May 24, 2024; the entire contents of which are incorporated herein by reference.

### FIELD

The present disclosure relates to a method for processing a wafer and a method for manufacturing chips.

### BACKGROUND

A wafer, on which chips are formed in a plurality of regions partitioned by a plurality of predetermined dividing lines (streets), and on which structures such as metal patterns are formed on the predetermined dividing lines, may be processed in a processing apparatus to form processing grooves along the predetermined dividing lines. As a result of the groove-forming process with the structures on the predetermined dividing lines, burrs may be generated and adhere to the chips.

For example, according to Japanese Patent Application Laid-Open Publication No. 2018-098296, processing grooves may be formed on a wafer by emitting laser beams at predetermined dividing lines, merely on areas where the metal structures are not arranged. Thereafter, a modified layer may be formed in the wafer along the predetermined dividing lines. When an external force is applied, the wafer in which the processing grooves and the modified layer are formed may be divided along the predetermined dividing lines. As such, burrs, which may be generated by the processing work to the structures arranged on the predetermined dividing lines, may be reduced.

### SUMMARY

Meanwhile, this processing method to form the processing grooves avoiding the metal structures may not be easily applied to a wafer, in which the structures occupy a large area in the predetermined dividing lines. Therefore, in a field of wafer processing, a method to form processing grooves in areas where structures are arranged while reducing burrs from chips is demanded.

An object of the present disclosure is to provide a method for processing a wafer and a method for manufacturing chips that may reduce burrs when forming processing grooves along predetermined dividing lines on which structures are arranged.

According to an aspect of the present disclosure, a method for processing a wafer to form a processing groove on the wafer along a predetermined dividing line, on at least a part of which a structure is formed, includes forming a first processing groove by removing the structure partly and leaving at least an end portion of the structure unremoved, the end portion including at least one end of the structure in a widthwise direction of the predetermined dividing line, and forming a second processing groove along the predetermined dividing line by removing the end portion of the structure being left in forming the first processing groove.

Optionally, the first processing groove and the second processing groove may be formed by emitting a laser beam at the wafer.

Optionally, a volume of the structure to be removed to form the first processing groove may be larger than a volume of the structure to be removed to form the second processing groove.

Optionally, output of the laser beam emitted to form the second processing groove may be smaller than output of the laser beam emitted to form the first processing groove.

Optionally, the first processing groove and the second processing grooves may be formed, respectively, by shifting a focused spot of the laser beam sequentially along an extending direction of the predetermined dividing line, and a distance between centers of adjacent focused spots of the laser beam emitted to form the first processing groove along the extending direction of the predetermined dividing line may be smaller than a distance between centers of adjacent focused spots of the laser beam emitted to form the second processing groove along the extending direction of the predetermined dividing line.

Optionally, a proportion of the structure to be left in forming the first processing groove in the widthwise direction of the predetermined dividing line may be within a range from 2% to 40%, inclusive, relative to a dimension of the structure in the widthwise direction.

According to another aspect of the present disclosure, a method for manufacturing a plurality of chips includes dividing the wafer along at least one of the first processing groove or the second processing groove formed in the method for processing the wafer.

According to the embodiments of the present disclosure, by leaving the end portions of the structures in forming the first processing groove and by removing the end portions in forming the second processing groove, burrs to be generated or adhere to chips when forming a processing groove along a predetermined dividing line may be reduced.

### BRIEF DESCRIPTION OF THE DRAWINGS

FIG. 1 is a perspective view of a wafer.

FIG. 2 is an enlarged top plan view of a predetermined dividing line on the wafer.

FIG. 3 is an illustrative view of a laser processing apparatus.

FIG. 4A is a cross-sectional view of a wafer before laser processing according to method for processing a wafer in a comparative example.

FIG. 4B is a cross-sectional view of the wafer after laser processing according to the method for processing a wafer in the comparative example.

FIG. 5 is a top plan view of the wafer according to the method for processing a wafer in the comparative example.

FIG. 6A is a cross-sectional view of a wafer to illustrate a first processing step in a method for processing a wafer according to a first embodiment.

FIG. 6B is a cross-sectional view of the wafer to illustrate a second processing step in the method for processing a wafer according to the first embodiment.

FIG. 6C is a cross-sectional view of the wafer after the second processing step in the method for processing a wafer according to the first embodiment.

FIG. 7A is a top plan view of the wafer in the first processing step in the method for processing a wafer according to the first embodiment.

FIG. 7B is a top plan view of the wafer in the second processing step in the method for processing a wafer according to the first embodiment.

FIG. 8A is a cross-sectional view of a wafer to illustrate a first processing step in a method for processing a wafer according to a second embodiment.

FIG. 8B is a cross-sectional view of the wafer to illustrate a second processing step in the method for processing a wafer according to the second embodiment.

FIG. 8C is a cross-sectional view of the wafer after the second processing step in the method for processing a wafer according to the second embodiment.

FIG. 9A is a cross-sectional view of a wafer to illustrate a first processing step in a method for processing a wafer according to a third embodiment.

FIG. 9B is a cross-sectional view of the wafer to illustrate a second processing step in the method for processing a wafer according to the third embodiment.

FIG. 9C is a cross-sectional view of the wafer after the second processing step in the method for processing a wafer according to the third embodiment.

FIG. 10 is an enlarged top plan view of a predetermined dividing line on the wafer with structures in a different arrangement.

FIG. 11A is a cross-sectional view of a wafer to illustrate a first processing step in a method for processing a wafer according to a fourth embodiment.

FIG. 11B is a cross-sectional view of the wafer to illustrate a second processing step in the method for processing a wafer according to the fourth embodiment.

FIG. 11C is a cross-sectional view of the wafer after the second processing step in the method for processing a wafer according to the fourth embodiment.

FIG. 12 is a table to show an example of processing settings and processed outcomes according to the embodiments.

FIG. 13A is a cross-sectional view of a wafer to illustrate a first processing step in a method for processing a wafer according to a fifth embodiment.

FIG. 13B is a cross-sectional view of the wafer to illustrate a second processing step in the method for processing a wafer according to the fifth embodiment.

FIG. 13C is a cross-sectional view of the wafer after the second processing step in the method for processing a wafer according to the fifth embodiment.

### DESCRIPTION OF EMBODIMENTS

Hereinbelow, embodiments of a method for processing a wafer and a method for manufacturing chips according to the present disclosure will be described with reference to the accompanying drawings. A Z-axis direction as indicated in each of the drawings is a direction of thickness of a wafer 10, which is in a form of a plate. An X-axis direction and a Y-axis direction are orthogonal to the Z-axis direction, and the X-axis direction and the Y-axis direction are orthogonal to each other. When processing the wafer 10, the wafer 10 is placed in an orientation such that the Z-axis direction is a vertical direction, and the X-axis direction and the Y-axis direction are horizontal directions.

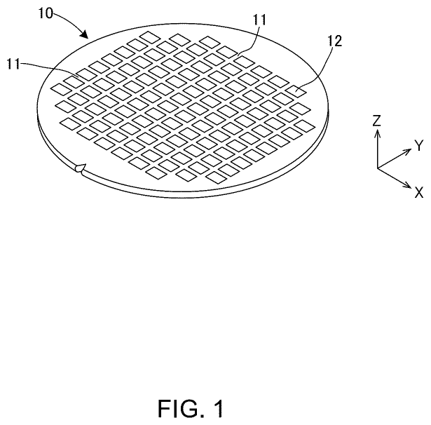

As shown in FIG. 1, the wafer 10 has a plurality of device regions on a surface thereof, which is sectioned in a grid pattern by predetermined dividing lines 11 extending in the X-axis direction and the Y-axis direction, and in each of the device regions, a chip 12 is formed. The predetermined dividing lines 11 may also be called streets. The wafer 10 may be, for example, a disk-shaped semiconductor wafer or optical device wafer, and may be made of a material such as silicon, sapphire, or gallium arsenide. The chips 12 may be semiconductor devices or optical devices. The material of the wafer 10 and the type of chips 12 are not necessarily limited. Optionally, the wafer 10 may be a single wafer or a laminated wafer composed of multiple wafers being bonded.

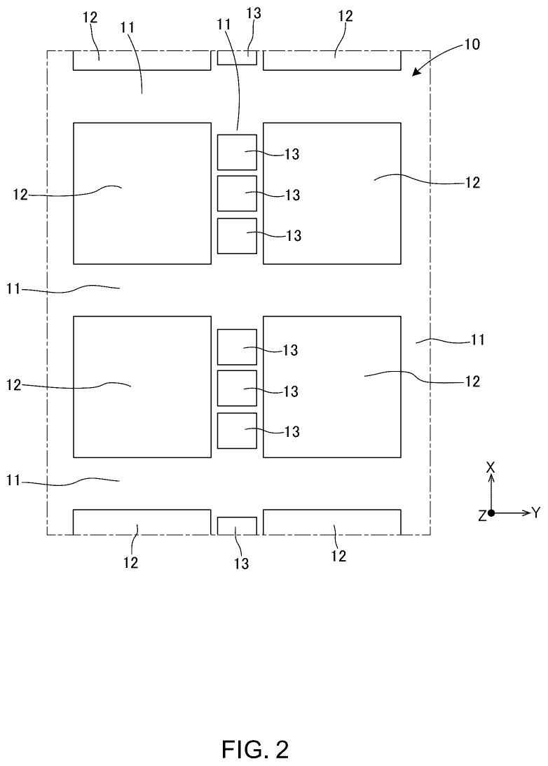

As shown in FIG. 2, on at least a part of the predetermined dividing lines 11, TEGs (Test Element Groups) 13 being metal structures are arranged. The TEGs 13 are a set of test elements used to evaluate characteristics of the devices before the wafer 10 is divided into a plurality of chips 12 and is formed of a predetermined metal pattern.

However, the structures to be disposed on the predetermined dividing lines 11 is not limited to TEGs. For example, in a configuration such as leads of a QFP (Quad Flat Package) where metal structures protrude from sides of each chip, and the protruding structures are arranged on the predetermined dividing lines 11, the present disclosure is applicable as well.

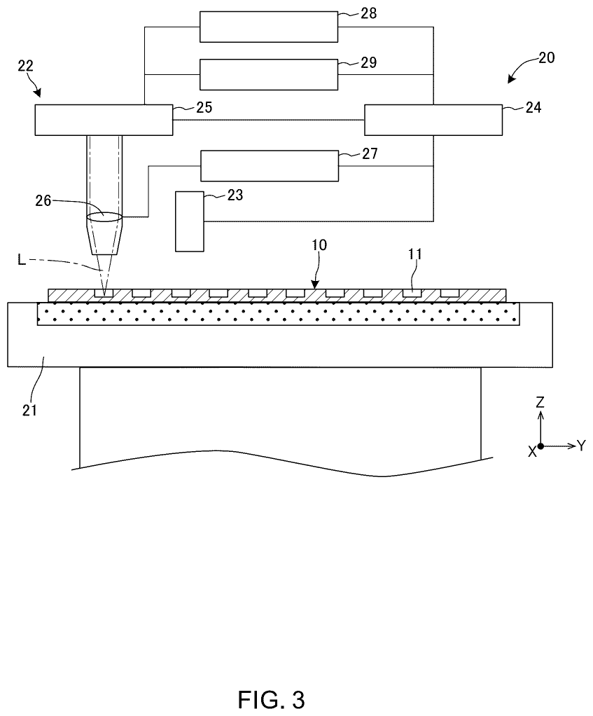

A processing apparatus 20 as shown in FIG. 3 is used to form processing grooves along the predetermined dividing lines 11 on the wafer 10. The processing apparatus 20 is a laser processing apparatus and includes a holder table 21 to hold the wafer 10, a laser emitter 22 that may emit a laser beam L at the wafer 10 on the holder table 21, and an image capturing device 23 that may capture an image of the wafer 10 on the holder table 21.

The components of the processing apparatus 20 are controlled by a control unit 24. The control unit 24 includes a processor to generate signals for controlling the components of the processing apparatus 20, and a memory to store various types of information. The processor may execute programs stored in the memory to control operations of the components of the processing apparatus 20. Operations to form the processing grooves along the predetermined dividing lines 11 are performed under the control of the control unit 24.

The holder table 21 has an upward-facing holder surface, on which the wafer 10 may be placed. This holder surface is formed of a porous material connected to a suction source (not shown), and the wafer 10 may be held in place against the holder surface by being suctioned through the suction source being driven.

The laser emitter 22 condenses the laser beam L from a laser oscillator 25 using a focusing optical system 26 to emit the laser beam L downward in the Z-axis direction. Although not shown in FIG. 3, the laser emitter 22 may include devices such as mirrors to form an optical path that guides the laser beam L from the laser oscillator 25 to the focusing optical system 26. A range irradiated with the laser beam L on a focal plane focused by the focusing optical system 26 is defined as a focused spot, and a diameter of the laser beam L at the focused spot is defined as a spot diameter. A distance from the focusing optical system 26 to the focal plane of the laser beam L is defined as a focal length, and a range along the optical axis where the focused laser beam L is assumed to be in focus, i.e., where energy from the laser beam L is most effectively achieved, is defined as a focal depth.

The laser oscillator 25 is configured to emit a pulsed laser beam, which has a wavelength absorbable by the wafer 10, as the laser beam L. As the wafer 10 is irradiated with the laser beam L along the predetermined dividing line 11, the location of the focused spot of the laser beam L is ablated, whereby the TEGs 13 and the wafer 10 are removed, and a processing groove is formed along the predetermined dividing line 11. The processing groove thus formed may be a bottomed half-cut groove that has a depth halfway through the thickness of the wafer 10 or a full-cut groove that penetrates entirely through the wafer 10. The control unit 24 controls output from the laser oscillator 25, thereby adjusting intensity of the laser beam L.

The focusing optical system 26 is a variable-focus optical system capable of changing the focal length by moving at least some of the lenses in an optical axis direction using an optical system adjuster 27, which includes, for example, a motor. By varying the focal length of the focusing optical system 26, the focal depth and spot diameter of the laser beam L are changed. Specifically, increasing the focal length of the focusing optical system 26 enlarges the focal depth and the spot diameter, and shortening the focal length reduces the focal depth and the spot diameter. The control unit 24 controls the optical system adjuster 27 to set the spot diameter of the laser beam L.

As another configuration of the laser emitter 22, optionally, a plurality of optical paths having different focal lengths may be provided, and the spot diameter may be changed by switching the optical paths through which the laser beam L passes.

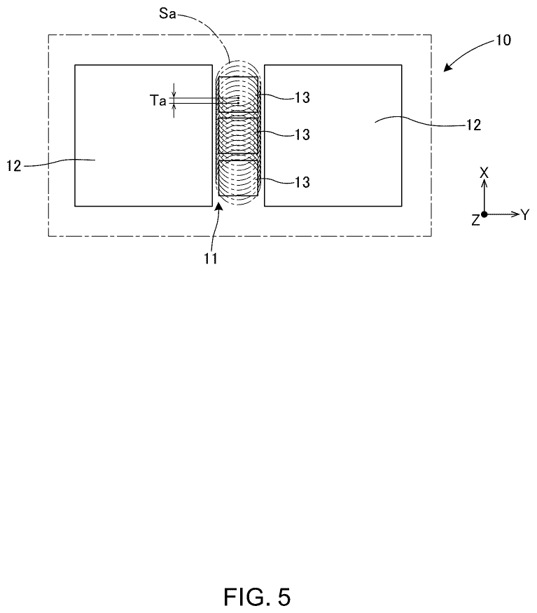

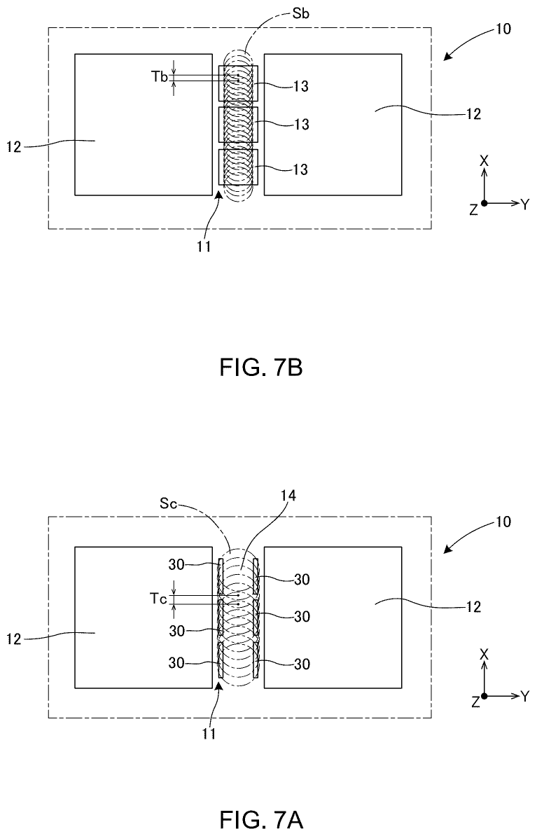

In a comparative example shown in FIG. 5 and the first embodiment shown in FIGS. 7A and 7B, the focused spot of the laser beam L is circular, but the shape of the focused spot is not limited to a circle but may be, for example, elliptical.

The laser emitter 22 is movable horizontally (the X-axis direction, the Y-axis direction) relatively to the holder table 21 through a horizontal motion assembly 28. Furthermore, the laser emitter 22 is movable vertically (the Z-axis direction) relatively to the holder table 21 through a lift/lower assembly 29. The horizontal motion assembly 28 and the lift/lower assembly 29 may each include, for example, a ball screw assembly in which a motor rotates a ball screw to move the laser emitter 22, and an air cylinder assembly which may move the laser emitter 22 using air pressure supplied from an air source. The control unit 24 may control the horizontal motion assembly 28 and the lift/lower assembly 29 to adjust the relative position between the wafer 10 held on the holder table 21 and the laser emitter 22, thereby changing the position to be irradiated with the laser beam L on the wafer 10.

Alternatively, the holder table 21 may be configured to be movable in the horizontal direction, so that the relative position between the wafer 10 and the laser emitter 22 may be adjusted not only by moving the laser emitter 22 via the horizontal motion assembly 28 but also by moving the holder table 21. For example, the horizontal motion assembly 28 may serve a role to move the holder table 21 in the X direction, while a movable assembly in the holder table 21 may serve a role to move the holder table 21 in the Y direction.

The control unit 24 operates the image capturing device 23 to capture an image of the wafer 10 on the holder table 21, and based on the captured image, arrange settings, such as a position setting, of the laser emitter 22 with respect to the wafer 10.

In the processing methods according to the embodiments described below, for setting the spot diameter of the focused spot of the laser beam L, the control unit 24 may determine the spot diameter based on the size of the TEGs 13 and TEGs 16 obtained from the images captured by the image capturing device 23. Alternatively, data concerning the sizes of the TEGs 13 and the TEGs 16 may be input in advance in the control unit 24 as processing settings, and the control unit 24 may refer to the information to determine the spot diameter.

Next, the processing method for forming processing grooves along the predetermined dividing line 11 on the wafer 10 where the TEGs 13 are arranged will be described. Hereinbelow, a comparative example and embodiments where the predetermined dividing line 11 extending in the X-axis direction is processed are described, and in the context, a lengthwise direction (extending direction) of the predetermined dividing line 11 corresponds to the X-axis direction, and a widthwise direction of the predetermined dividing line 11 corresponds to the Y-axis direction. Not only the predetermined dividing lines 11 extending in the X-axis direction, needless to say, but also the predetermined dividing lines 11 extending in the Y-axis direction may be processed in the same processing method.

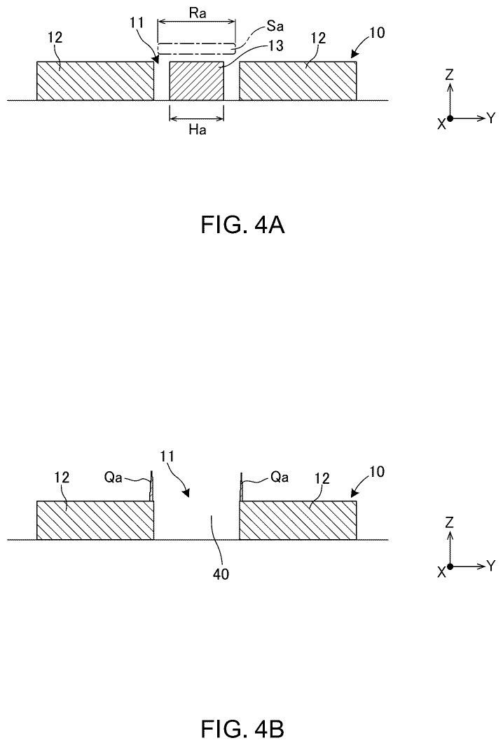

FIGS. 4A, 4B, and 5 illustrate a comparative processing method different from the processing methods according to the embodiments of the present disclosure. In this comparative example, as shown in FIG. 4A, a spot diameter Ra of a focused spot Sa of the laser beam L is set to be larger than a length Ha of the TEGs 13 in the widthwise direction (Y-axis direction) of the predetermined dividing line 11. A position to be irradiated with the laser beam L in the widthwise direction of the predetermined dividing line 11 is set in an arrangement such that a range of the focused spot Sa covers the length Ha of the TEG 13 entirely. In other words, the laser beam L is in a setting such that the entire TEGs 13 may be removed and a processing groove 40 may be formed by a single run of the laser beam L. Note that, although FIG. 4A shows the focused spot Sa at a position spaced above the wafer 10, in an actual operation, the irradiation position with the laser beam L in the Z-axis direction is adjusted so that the focused spot Sa reaches a range of the thickness of the wafer 10 (the position of the TEGs 13).

With the processing settings as described above, and as shown in FIG. 5, the irradiation position with the laser beam L, i.e., the position of the focused spot Sa, on the wafer 10 is sequentially shifted along the lengthwise direction (extending direction, the X-axis direction) of the predetermined dividing line 11, thereby sequentially removing the plurality of TEGs 13 on the predetermined dividing line 11 by ablating with the laser beam L. A distance between centers of the focused spots adjacent to each other in the lengthwise direction of the predetermined dividing line 11 is set to a predetermined distance Ta. As a result, as shown in FIG. 4B, a processing groove 40, from which the TEGs 13 are removed, is formed between chips 12 that are adjacent to each other across the predetermined dividing line 11.

As shown in FIG. 4B, when the TEGs 13 being metal structures are removed by ablation with the laser beam L, burrs Qa which are spiky protrusions may be generated on both sides of the processing groove 40. Each TEG 13 before removal has the length Ha in the widthwise direction of the predetermined dividing line 11, which is approximate to the distance between the adjacent chips 12, reserving merely a narrow gap between the TEGs 13 and the chips 12 on each side of the predetermined dividing line 11. Therefore, if an operation to remove the entire TEGs 13 having the length Ha is performed in a single run of the laser beam L with the focused spot Sa having the spot diameter Ra larger than the length Ha of the TEGs 13, large burrs Qa may be formed on the chips 12 located on the both sides of the processing groove 40 as a result of the ablation. The burrs Qa with a large amount of upward height may require a considerable length of time to remove in a post-processing deburring operation, thereby increasing an overall processing time for the wafer 10.

Moreover, in order to remove the TEGs 13 with a large volume in a single run of laser irradiation, it may be necessary to set the output of the laser beam L to a high level. When the laser beam L of the high-output level is emitted along the predetermined dividing line 11 with the large spot diameter Ra, the chips 12 on the both sides of the predetermined dividing line 11 may be affected by the laser beam L and may be heated, and negative impacts such as reduced flexural strength may be caused in the chips 12.

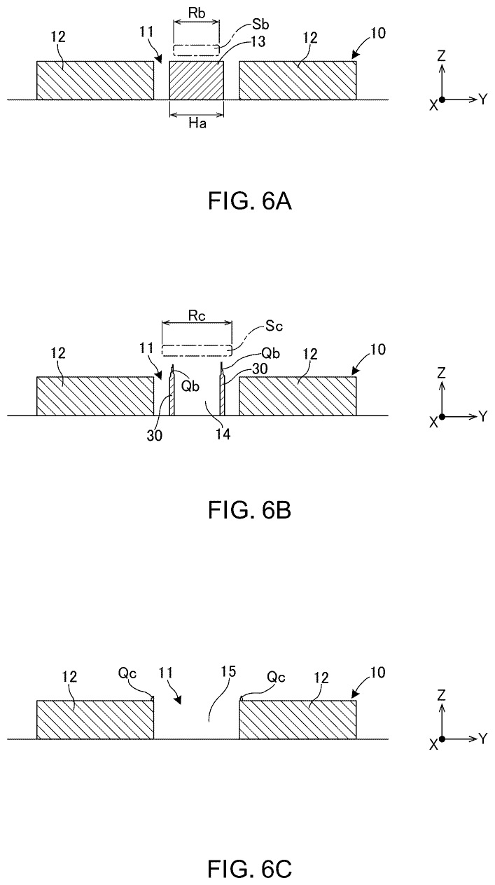

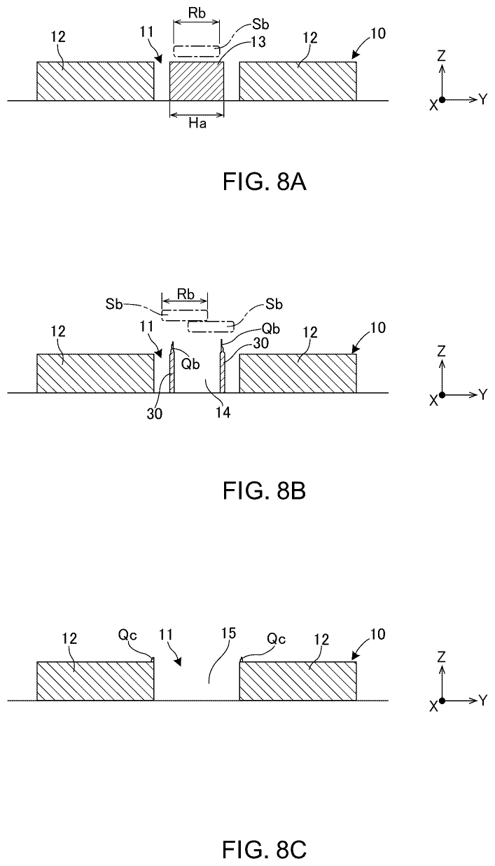

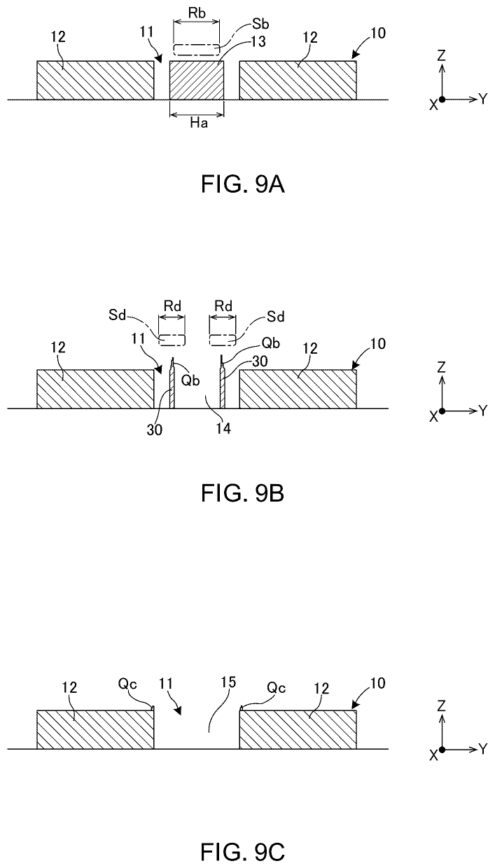

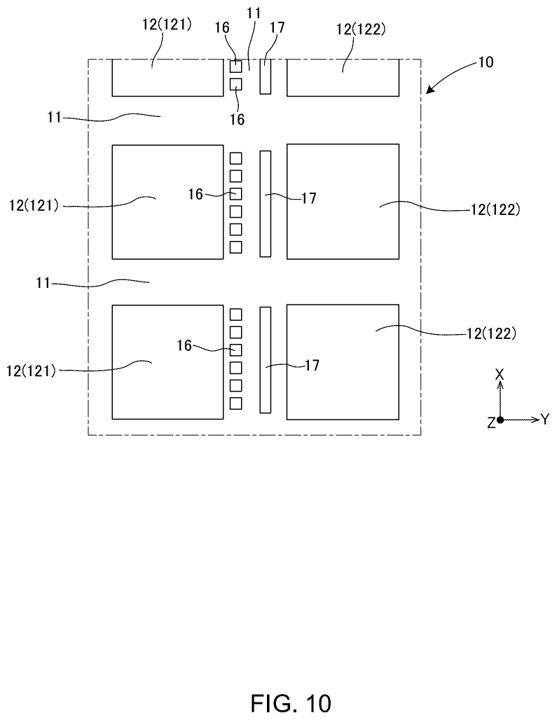

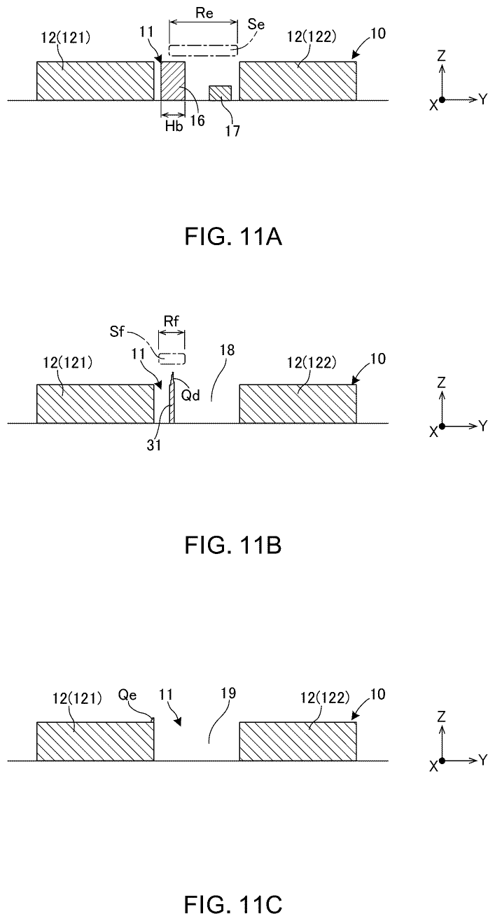

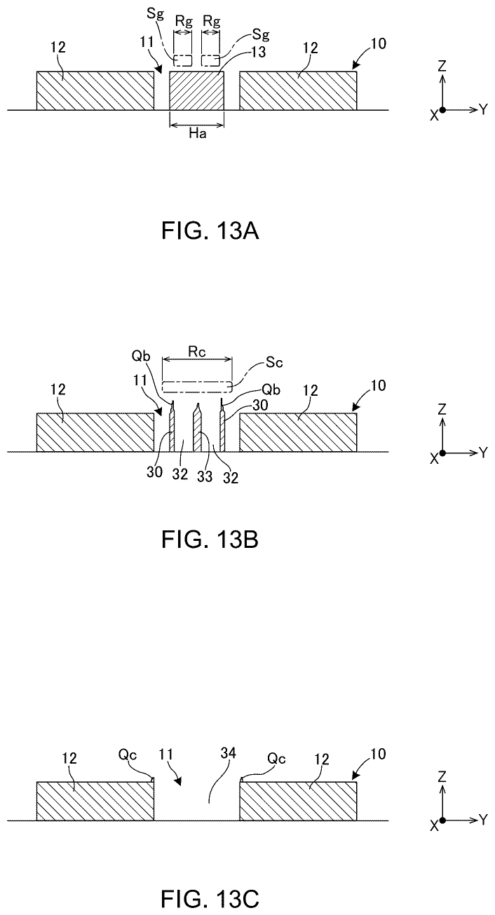

Next, methods for processing a wafer according to the embodiments of the present disclosure, which differ from the above comparative example, are described. FIGS. 6A, 6B, 6C, 7A, and 7B illustrate the processing method of a first embodiment; FIGS. 8A, 8B, and 8C illustrate a second embodiment; and FIGS. 9A, 9B, and 9C illustrate a third embodiment. FIG. 10 shows a part of the wafer 10 in a modified example, in which the structures on the predetermined dividing lines 11 are in a different arrangement, and FIGS. 11A, 11B, and 11C illustrate the processing method according to a fourth embodiment corresponding to the wafer 10 modified as such. FIGS. 13A, 13B, and 13C illustrate the processing method according to a fifth embodiment. In cross-sectional views of the wafer 10 for the embodiments (i.e., FIGS. 6A-6C, 8A-8C, 9A-9C, 11A-11C, and 13A-13C), focused spots Sb, Sc, Sd, Se, Sf, and Sg of the laser beam L are drawn at positions spaced above the wafer 10. However, in actual operations, the irradiation position of the laser beam L in the Z-axis direction is adjusted so that the focused spot reaches a range of the thickness of the wafer 10, i.e., the position of the TEGs 13 or the TEGs 16.

### [First Processing Step]

FIGS. 6A and 7A illustrate a first processing step in the processing method according to the first embodiment. As shown in FIG. 6A, in the first processing step, the control unit 24 sets a spot diameter Rb of a focused spot Sb of the laser beam L to be smaller than the length Ha of the TEG 13 in the widthwise direction (the Y-axis direction) of the predetermined dividing line 11.

The length Ha of the TEGs 13 may be obtained from the image captured by the image capturing device 23 or may be obtained from the data included in the processing settings input to the control unit 24. A numerical value of the spot diameter Rb with respect to the length Ha of the TEGs 13 may be stored in advance as table data in the memory of the control unit 24. Alternatively, a calculation formula for determining an appropriate spot diameter Rb based on the length Ha of the TEGs 13 may be stored in the memory, and the control unit 24 may compute the spot diameter Rb based on that formula. In any case, the control unit 24 adjusts the focal length of the focusing optical system 26 in the laser emitter 22 in correspondence with the spot diameter Rb having been set.

Next, the control unit 24 sets the position of the laser emitter 22 such that end portions of the TEGs 13 in the widthwise direction of the predetermined dividing line 11 are not included in the range of the focused spot Sb and operates the laser emitter 22 to emit the laser beam L at the wafer 10. As shown in FIG. 7A, the control unit 24 sets a distance between centers of the focused spots Sb that are adjacent in the lengthwise direction (extending direction, the X-axis direction) of the predetermined dividing line 11 to a predetermined distance Tb, and sequentially shifts the irradiation position of the laser beam L (position of the focused spot Sb) along the lengthwise direction of the predetermined dividing line 11 to ablate with the laser beam L.

As shown in FIGS. 6B and 7B, by performing the first processing step as above, the widthwise central portion of each TEG 13 arranged on the predetermined dividing line 11, which is within the range of the focused spot Sb and irradiated with the laser beam L, is removed, while end portions 30 on the both sides in the widthwise direction that are outside the range of the focused spot Sb are left unremoved. A first processing groove 14 is thus formed between the remaining end portions 30. Meanwhile, burrs Qb are generated while the first processing groove 14 is formed and adhere to upper ends of the end portions 30. In other words, in the first processing step, the end portions 30 left on the both sides in the widthwise direction of the predetermined dividing line 11 function as protective walls, which prevent burrs from being adhering to the chips 12.

### [Second Processing Step]

FIGS. 6B and 7B illustrate a second processing step in the processing method according to the first embodiment. As shown in FIG. 6B, in the second processing step, the control unit 24 sets the focal length of the focusing optical system 26 of the laser emitter 22 so that a spot diameter Rc of a focused spot Sc of the laser beam L becomes greater than or equal to the length Ha of the removed TEGs 13 in the widthwise direction of the predetermined dividing line 11. In other words, the spot diameter Rc of the focused spot Sc is set to a size such that the end portions 30 remaining on the both sides in the widthwise direction of the predetermined dividing line 11 may be simultaneously irradiated with the laser beam L. The numerical value of the spot diameter Rc corresponding to the length Ha of the removed TEGs 13 may be stored in the memory of the control unit 24 as table data or may be calculated by the control unit 24 based on a stored formula. In any case, the control unit 24 adjusts the focal length of the focusing optical system 26 in accordance with the spot diameter Rc having been set.

Next, the control unit 24 sets the position of the laser emitter 22 such that the end portions 30 are included in a range of the focused spot Sc in the widthwise direction of the predetermined dividing line 11 and operates the laser emitter 22 to emit the laser beam L at the wafer 10. As shown in FIG. 7B, the control unit 24 sets a distance between centers of the focused spots Sc that are adjacent in the lengthwise direction (extending direction, the X-axis direction) of the predetermined dividing line 11 to a predetermined distance Tc, and sequentially shifts the irradiation position of the laser beam L (position of the focused spot Sc) along the lengthwise direction of the predetermined dividing line 11 to ablate with the laser beam L.

As shown in FIG. 6C, by performing the second processing step as above, the end portions 30 included in the range of the focused spot Sc are irradiated with the laser beam L and removed, thereby forming a second processing groove 15, which is wider than the first processing groove 14 formed in the first processing step, between the chips 12 that are adjacent in the Y-axis direction.

In the second processing step, as a result of removal of the end portions 30 that served as the protective walls in the first processing step, burrs Qc may be generated while the second processing groove 15 is being formed and adhere to the chips 12 located on the both sides of the second processing groove 15, as shown in FIG. 6C. However, a volume of the end portions 30 removed in the second processing step is smaller than the volume of the TEGs 13 that originally existed before the first processing step; therefore, the burrs Qc generated in the second processing step, where the volume of the metal patterns to be removed is small, are considerably smaller than the burrs Qa generated in the comparative method shown in FIGS. 4A and 4B. Accordingly, the burrs Qc after the second processing step may be removed easily without efforts, and the chips 12 in superior quality may be manufactured efficiently.

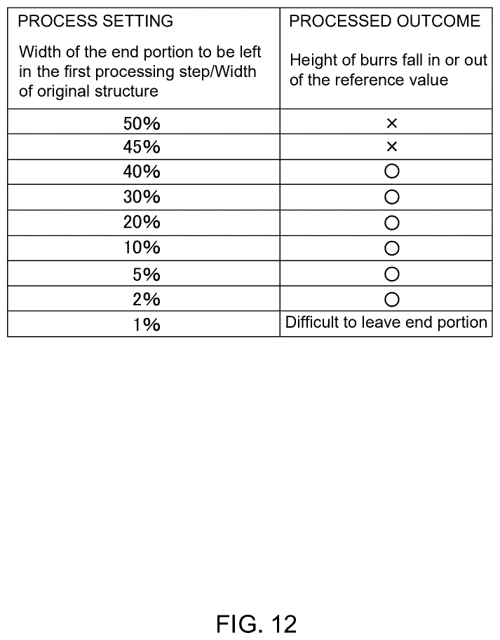

As the volume of the end portions 30 to be removed in the second processing step is reduced, the size of the burrs Qc to be generated in the second processing step is reduced effectively. At least, it is preferable that the volume of the structures (the widthwise central portions of the TEGs 13) to be removed in the first processing step is larger than the volume of the structures (the end portions 30 on the widthwise sides of the predetermined dividing line 11) to be removed in the second processing step. More specific settings regarding the proportion of the end portions to be left after the first processing step will be described later with reference to FIG. 12.

Although the spot diameter of the focused spot of the laser beam L differs between the first processing step and the second processing step, other laser processing settings may be either the same or different between the first processing step and the second processing step. Such laser processing settings other than the spot diameter may include, for example, the output of the laser beam L from the laser oscillator 25 and the processing intervals in the lengthwise direction of the predetermined dividing line 11 (i.e., the distance between the centers of the adjacent focused spots).

The control unit 24 may set the output of the laser beam L to be emitted in the first processing step and the output of the laser beam L to be emitted in the second processing steps to be either the same or different. When the volume of the structures to be removed in the first processing step is larger than the volume of the structures to be removed in the second processing step, higher ablation performance is required in the first processing step. In other words, the ablation performance required in the second processing step is relatively low to that of the first processing step. Therefore, when the levels of the laser outputs are differed between the first and second processing steps, it is preferable that the control unit 24 sets the output of the laser beam L in the second processing step to be lower than the output of the laser beam L in the first processing step. By doing so, in the second processing step, in which the laser beam L is emitted at the positions closer to the chips 12 in the widthwise direction of the predetermined dividing line 11, the laser beam L of the lowered output is emitted, and impacts on the chips 12 by the laser beam L, such as degradation in flexural strength, may be reduced. Moreover, energy to be consumed in the second processing step may be effectively saved.

Optionally, the control unit 24 may set the distance Tb between the centers of the focused spots Sb in the first processing step and the distance Tc between the centers of the focused spots Sc in the second processing step to be either the same or different. In the example shown in FIGS. 7A and 7B, the control unit 24 sets the distance Tb between the centers of the focused spots Sb in the first processing step to be smaller than the distance Tc between the centers of the focused spots Sc in the second processing step. According to this setting, in the first processing step, in which the volume of the structures to be removed is larger, the laser beam L in high density may be emitted at smaller intervals in the lengthwise direction of the predetermined dividing line 11 so that the level of the energy per unit area to ablate the structure may be increased. On the other hand, in the second processing step, in which the volume of the structure to be removed is smaller, the laser beam L in low density may be emitted at larger intervals in the lengthwise direction of the predetermined dividing line 11 so that the structures may be ablated with superior energy efficiency and time efficiency.

As described above, the control unit 24 may adjust the output of the laser beam L and the intervals between the focused spots based on the volume of the structures to be removed in the first processing step and the second processing step. As such, laser processing optimized to the respective processing steps may be performed, and, while minimizing burr formation on the chips 12, the first processing groove 14 and the second processing groove 15 may be formed efficiently.

Referring now to FIGS. 8A, 8B, and 8C, a processing method according to a second embodiment will be described. A first processing step shown in FIG. 8A is performed in the same manner as the first processing step in the first embodiment. The laser beam L, having the spot diameter Rb of the focused spot Sb smaller than the length Ha of the TEGs 13 in the widthwise direction of the predetermined dividing line 11, is emitted while sequentially shifting the position of focused spot Sb along the lengthwise direction of the predetermined dividing line 11. Accordingly, the first processing groove 14 is formed between the end portions 30, which are left unremoved on the both sides of the predetermined dividing line 11 in the widthwise direction.

In the second processing step shown in FIG. 8B, the spot diameter Rb of the focused spot Sb is set to the same size as the spot diameter Rb in the first processing step, and the end portions 30 left unremoved in the first processing step are irradiated with the laser beam L. As the spot diameter Rb of the focused spot Sb is not large enough to cover both of the end portions 30 simultaneously, processing with the laser beam L is performed in two runs. In a first run, the irradiation position is set such that the focused spot Sb covers one of the end portions 30 in the widthwise direction of the predetermined dividing line 11, and the position of the focused spot Sb is sequentially shifted along the lengthwise direction of the predetermined dividing line 11 to emit the laser beam L and remove the one of the end portions 30. Next, in a second run, the irradiation position is set such that the focused spot Sb covers the other one of the end portions 30, and the laser beam L is emitted while shifting the position sequentially along the lengthwise direction to remove the other one of the end portions 30. As a result, as shown in FIG. 8C, the second processing groove 15 is formed. Optionally, the laser beam L may be split in the Y-axis direction to form two focused spots Sb along the widthwise direction of the predetermined dividing line 11.

In the processing method according to the second embodiment, in the same manner as the first embodiment, the first processing groove 14 is formed in the first processing step while leaving the end portions 30 on the both sides of the predetermined dividing line 11 unremoved, and in the second processing step, the end portions 30 on the both side of the predetermined dividing line 11 are removed to form the second processing groove 15. This may prevent burrs Qb from adhering to the chips 12 while the first processing groove 14 is formed and may reduce a volume of the burrs Qc to adhere to the chips 12 when the second processing groove 15 is formed.

Furthermore, in the second embodiment, the laser beam L with the same spot diameter Rb is used in the first processing step and the second processing step. Therefore, no effort to change the spot diameter of the laser beam L is necessary, and the settings of the laser emitter 22 for the laser processing may be simplified. This method is therefore applicable to a laser emitter, of which spot diameter is invariable, unlike the laser emitter 22, as well.

Referring to FIGS. 9A, 9B, and 9C, a processing method according to a third embodiment will be described. A first processing step shown in FIG. 9A is performed in the same manner as the first processing step in the first embodiment. The laser beam L, having the spot diameter Rb of the focused spot Sb smaller than the length Ha of the TEGs 13 in the widthwise direction of the predetermined dividing line 11, is emitted while sequentially shifting the position of focused spot Sb along the lengthwise direction of the predetermined dividing line 11. Accordingly, the first processing groove 14 is formed between the end portions 30, which are left unremoved on the both sides of the predetermined dividing line 11 in the widthwise direction.

In the second processing step shown in FIG. 9B, a spot diameter Rd of a focused spot Sd is set to be smaller than the spot diameter Rb of the focused spot Sb in the first processing step, and the end portions 30 left unremoved in the first processing step are irradiated with the laser beam L. As the spot diameter Rd of the focused spot Sd is not large enough to cover both of the end portions 30 simultaneously, processing with the laser beam L is performed in two runs. In a first run, the irradiation position is set such that the focused spot Sd covers one of the end portions 30 in the widthwise direction of the predetermined dividing line 11, and the position of the focused spot Sd is sequentially shifted along the lengthwise direction of the predetermined dividing line 11 to emit the laser beam L and remove the one of the end portions 30. Next, in a second run, the irradiation position is set such that the focused spot Sd covers the other one of the end portions 30, and the laser beam L is emitted while shifting the position sequentially along the lengthwise direction to remove the other one of the end portions 30. As a result, as shown in FIG. 9C, the second processing groove 15 is formed. Optionally, the laser beam L may be split in the Y-axis direction to form two focused spots Sd along the widthwise direction of the predetermined dividing line 11.

In the processing method according to the third embodiment, in the same manner as the first embodiment, the first processing groove 14 is formed in the first processing step while leaving the end portions 30 on the both sides of the predetermined dividing line 11 unremoved, and in the second processing step, the end portions 30 on the both side of the predetermined dividing line 11 are removed to form the second processing groove 15. This may prevent burrs Qb from adhering to the chips 12 while the first processing groove 14 is formed and may reduce a volume of the burrs Qc to adhere the chips 12 when the second processing groove 15 is formed.

Furthermore, in the processing method according to the third embodiment, in the second processing step, the laser beam L with the spot diameter Rd narrowed to the range of one of the end portions 30 to be removed is emitted, without overlapping the range where first processing groove 14 is formed in the first processing step performed earlier. Therefore, the power of the laser beam M may be used efficiently, and the wafer 10 may be processed energy-efficiently.

In the processing methods according to the second embodiment and the third embodiment, settings for laser processing other than the spot diameter, such as output of the laser beam L, distance between the centers of the adjacent focused spots, etc., may be configured in the same manner as those in the first embodiment. In other words, the settings for the laser processing other than the spot diameter, such as output power of the laser beam L, distance between the centers of the adjacent focused spots, etc., may either be the same or different between the first processing step and the second processing step.

In the processing methods according to the second embodiment and the third embodiment, in a case where the laser processing settings other than the spot diameter are configured to be different between the first processing step and the second processing step, for example, the control unit 24 may set the output of the laser beam L in the second processing step to be lower than the output of the laser beam L in the first processing step. Moreover, the distance between the centers of the adjacent focused spots Sb in the first processing step may be set to be smaller than the distance between the adjacent focused spots Sb, Sd in the second processing step. With the settings optimized as above, the first processing step, in which the volume of the structure to be removed is larger, and the second processing step, in which the volume of the structure to be removed is smaller, may be performed preferably.

FIG. 10 shows a modified example of the wafer 10, where a plurality of TEGs 16 are located at positions offset to one side in the widthwise direction from the center of the predetermined dividing line 11. On the predetermined dividing line 11, non-metal structures 17 made of non-metal patterns are arranged at a position offset in the widthwise direction from the center of the predetermined dividing line 11 on a side opposite to the TEGs 16. First chips 121 are the chips 12 located closer to the TEGs 16 in the widthwise direction of the predetermined dividing line 11, and second chips 122 are the chips 12 located closer to the non-metal structure 17 in the widthwise direction of the predetermined dividing line 11.

FIGS. 11A, 11B, and 11C illustrate a fourth embodiment of the method to process the wafer 10, on which the TEGs 16 and the non-metal structures 17 are arranged on the predetermined dividing line 11. In the first processing step shown in FIG. 11A, the control unit 24 sets a spot diameter Re of a focused spot Se of the laser beam L to cover a portion of the TEG 16 and the entire non-metal structure 17 in the widthwise direction of the predetermined dividing line 11. In other words, the spot diameter Re is in a size to include a portion of the TEG 16, the entirety of the non-metal structure 17, and the space between the TEG 16 and the non-metal structure 17 in the widthwise direction. The spot diameter Re is larger than a length Hb of the TEGs 16 in the widthwise direction. The non-metal structure 17 may not necessarily be provided but may optionally be omitted. In the case where the non-metal structures 17 are not provided, the spot diameter of the focused spot of the laser beam L in the first processing step should cover the length Hb of the TEG 16 at least partly.

Next, the control unit 24 sets the irradiation position such that an end portion 31 of the TEG 16 on a side closer to the first chip 121 to be left, operates the laser emitter 22 to emit the laser beam L at the wafer 10, and sequentially shifts the irradiation position of the laser beam L (position of the focused spot Se) along the lengthwise direction of the predetermined dividing line 11 to ablate with the laser beam L.

As shown in FIG. 11B, by performing the first processing step described above, the portions (regions toward the second chips 122) of the TEGs 16 on the predetermined dividing line 11 included in the range of the focused spot Se are irradiated with the laser beam L and removed, thereby leaving the end portions 31, which are the portions of the TEGs 16 toward the first chips 121 excluded from the range of the focused spot Se. Meanwhile, the non-metal structures 17 on the predetermined dividing line 11 are entirely included in the range of the focused spot Se in the widthwise direction and therefore removed entirely in the first processing step. As a result, a first processing groove 18 is formed in the region excluding the remaining end portions 31 near the first chips 121.

As a result of processing the TEGs 16 with the laser beam L in order to form the first processing groove 18, burrs Qd may be generated and adhere to an upper surface of the end portions 31 being left. In other words, the end portions 31 left on one side in the widthwise direction of the predetermined dividing line 11 in the first processing step may serve as protective walls to prevent the burrs from adhering to the first chips 121, which are located closer to the TEGs 16. On the other hand, the second chips 122, which are located farther from the TEGs 16, are substantially distanced from the TEGs 16. Therefore, when the regions of the TEGs 16 toward the second chips 122 are removed in the first processing step, even without leaving any end portions, the burrs may not reach the second chips 122. As such, when the distance from the chips 12 to the TEGs 16 on one side and the distance from the chips 12 to the TEGs 16 on the other side in the widthwise direction are not equal, in the first processing step, the end portions 31 including ends of the TEGs 16 solely on the side closer to the chips 12 may be left unprocessed so that the burrs to adhere to the chips 12 may be reduced.

As for the non-metal structures 17, even when the non-metal structure 17 is removed entirely in the first processing step, it may not cause burrs to adhere to the second chips 122. Therefore, substantially no burrs may adhere to the second chips 122, which are on the farther side from the TEGs 16.

In the second processing step shown in FIG. 11B, a spot diameter Rf of a focused spot Sf of the laser beam L is set to be smaller than the spot diameter Re of the focused spot Se in the first processing step in order to emit the laser beam L at the end portions 31 left unremoved in the first processing step. The spot diameter Rf is set to a minimum size required to cover the width of the end portions 31, similarly to the spot diameter Rd (see FIG. 9B) of the focused spot Sd in the third embodiment. The irradiation position is set such that the focused spot Sf covers the end portion 31 in the widthwise direction of the predetermined dividing line 11, and the position of the focused spot Sf is sequentially shifted along the lengthwise direction of the predetermined dividing line 11 to emit the laser beam L and remove the end portions 31. As a result, as shown in FIG. 11C, a second processing groove 19 is formed. Burrs Qe may be generated when the end portions 31 are removed and adhere to the first chips 121.

In the processing method according to the fourth embodiment, the first processing groove 18 is formed in the first processing step while leaving the end portions 31 on one side in the widthwise direction of the predetermined dividing line 11, and in the second processing step, the end portions 31 are removed to form the second processing groove 19. This may prevent the burrs Qd from adhering to the chips 12 (the first chips 121 and the second chips 122) while the first processing groove 18 is formed and may reduce a volume of the burrs Qe to adhere to the chips 12 (the first chips 121) when the second processing groove 19 is formed.

In the processing method according to the fourth embodiment, settings for the laser processing other than the spot diameter, such as output of the laser beam L, distance between the centers of the adjacent focused spots, etc., may be configured in the same manner as those in the first embodiment. In other words, the settings for the laser processing other than the spot diameter, such as output power of the laser beam L, distance between the centers of the adjacent focused spots, etc., may either be the same or different between the first processing step and the second processing step.

In the processing method according to the fourth embodiment, in the case where the laser processing settings other than the spot diameter are set to be different between the first processing step and the second processing step, for example, the control unit 24 may set the output of the laser beam L in the second processing step to be lower than the output of the laser beam L in the first processing step. Moreover, the distance between the centers of the adjacent focused spots Se in the first processing step may be set to be smaller than the distance between the adjacent focused spots Sf in the second processing step. With the settings optimized as above, the first processing step, in which the volume of the structure to be removed is larger, and the second processing step, in which the volume of the structure to be removed is smaller, may be performed preferably.

In the processing methods according to the above embodiments (first through fourth embodiments), it is preferable that at least the volume of the metal structures to be removed in the first processing step (i.e., the portions of TEGs 13 or the TEGs 16 to be removed) to be larger than the volume of the metal structures to be removed in the second processing step (the end portions 30 or the end portions 31). As previously mentioned, as the volume of the portions to be removed in the second processing step is reduced, the size of the burrs to be caused in the second processing step may be reduced effectively.

The table in FIG. 12 shows an example of experimental results demonstrating the relation between processing settings for the end portions of the metal structures to be left in the first processing step and the final processing outcome, i.e., burr formation on the chips after the second processing step.

The numerical values in a column on the left of the table in FIG. 12 represent a ratio of the width of the end portions (end portions 30 or end portions 31) of the metal structure to be left in the first processing step with respect to the original width (length in the widthwise direction of the predetermined dividing line 11) of the metal structures (TEGs 13 or TEGs 16) located before the first processing step is performed on the predetermined dividing line 11. FIG. 12 shows that, as the numerical value is lowered, the proportion of the width of the end portions of the metal structures to be left in the first processing step becomes smaller, and the volume of the metal structures to be left in the first processing step becomes smaller. In other words, as the numerical value is increased, the proportion of the volume of the remaining portions to be removed in the second processing step becomes larger.

The column on the right in the table in FIG. 12 shows results of judging whether the height of the burrs adhered to the chips 12 after the second processing step is smaller than or equal to a reference value (tolerance value), where a circle (o) represents a preferable result that the height is smaller than or equal to the reference value and a cross (x) represents that the height exceeded the reference value. As shown in FIG. 2, in the case where the width of the TEGs 13 in the predetermined dividing line 11 is relatively large and where burrs are likely to be formed on the chips 12 on the both sides of the predetermined dividing line 11, the judgement may be made based on the height of the burrs on the chips 12 on each side. As shown in FIG. 10, in the case where the TEGs 16 are located offset from the widthwise center of the predetermined dividing line 11 and where the burrs are likely to be formed on the chips 12 (first chips 121) on solely the one side of the predetermined dividing line 11, the judgement may be made based on solely the height of the burrs formed on the chips 12 on the one side.

As may be seen in the experimental results, when the proportion of the width of the end portions (end portions 30 or end portions 31) of the metal structures to be left in the first processing step is increased to 45% or more of the original width of the metal structures, the amount of the remaining portions to be removed in the second processing step increases, and the height of the burrs may exceed the reference value. Therefore, even if the first processing groove and the second processing groove are formed in the two steps, adherence of the burrs to the chips 12 may not be reduced or avoided effectively. In other words, the result shows no significant difference in burr formation compared to the case, as shown in the comparative example in FIGS. 4A, 4B, and 5, where the metal structures are removed without leaving the end portions unprocessed.

On the other hand, when the proportion of the width of the end portions of the metal structures to be left in the first processing step is lowered to 1% or less of the original width of the metal structures, the result shows that the processed outcome may be uncertain such that, for example, the metal structures may be entirely removed without leaving the end portions, and it is difficult to leave the end portions with the desired width reliably.

The above experimental results suggest a preferable dimensional relation in the widthwise direction of the predetermined dividing line 11 such that the proportion of the width of the end portion of the metal structure to be left unremoved in the first processing step with respect to the width of the metal structure before the process may be within a range of approximately 2% to 40%.

As described above, according to the embodiments of the methods for processing a wafer, in the first processing step, the first processing groove 14, 18 is formed by processing the wafer 10, leaving the end portions 30, 31 of the TEGs 13, 16 being the structures on the predetermined dividing line 11, and in the second processing step, the second processing groove 15, 19 is formed by removing the end portions 30, 31. Thereby, burrs that may adhere to the chips when the processing groove is formed along the predetermined dividing line 11 may be reduced.

By dividing the wafer 10 along the processing grooves formed in the methods as described above, a plurality of chips 12 may be manufactured from the wafer 10.

In particular, in a case where the first processing groove 14, 18 formed in the first processing step or the second processing groove 15, 19 formed in the second processing step are full-cut grooves that are formed fully through the wafer 10 in the thickness direction, the wafer 10 is divided into the individual chips 12 at the time when the full-cut grooves are formed. Therefore, a tape (not shown) may be bonded to a back side of the wafer 10, which is a side opposite to the side on which the chips 12 are formed, before the wafer 10 is processed in the processing apparatus 20 so that the individual chips 12 divided by the full-cut grooves may be maintained in the predetermined positions relative to one another through the tape. Accordingly, the chips 12 in the state held together through the tape may be deburred preferably.

In a case where the first processing groove 14, 18 formed in the first processing step or the second processing groove 15, 19 formed in the second processing step are half-cut grooves with bottoms that are formed halfway through the wafer 10 in the thickness direction, the wafer 10 may be divided at the half-cut grooves by applying an external force after the half-cut grooves are formed or by applying an external force after the half-cut grooves are formed and a modified layer is formed in the wafer 10 along the predetermined dividing lines 11 additionally to the half-cut grooves. The chips 12 may be deburred after the half-cut grooves are formed, either before the wafer 10 is divided at the half-cut grooves or after the wafer 10 is divided into the chips 12, similarly to the above case of the full-cut grooves.

In the methods for processing a wafer according to the embodiments described above, the first processing grooves 14, 18 in the first processing step and the second processing grooves 15, 19 in the second processing step are both formed by irradiation with the laser beam, but the method for forming processing grooves in the processing steps is not necessarily limited to this. For example, the first processing grooves may be formed by being cut mechanically with a dicing blade, and the second processing grooves may be formed by being irradiated with the laser beam.

In the methods for processing a wafer according to the embodiments described above, the first processing groove 14, 18 along a single predetermined dividing line 11 is formed in a single laser processing operation. However, as another example of the first processing step, the first groove may be formed in multiple steps. For example, for forming a first processing groove, a groove with a smaller width may be formed initially, and the width of the initial groove may be expanded gradually to complete the first processing groove.

In the first through third embodiments described above, merely the end portions 30 on the both sides of the TEGs 13 are left in the first processing step. However, as a modified example, a plurality of first processing grooves may be formed between the end portions 30 to leave a central portion of the TEGs 13 between the plurality of processing grooves.

FIGS. 13A, 13B, and 13C illustrate a fifth embodiment being the modified example of the processing method. In the first processing step shown in FIG. 13A, the control unit 24 sets a spot diameter Rg of a focused spot Sg of the laser beam L to be smaller than a half of the length Ha of the TEGs 13 in the widthwise direction of the predetermined dividing line 11. The control unit 24 sequentially shifts the position of the focused spot Sg along the lengthwise direction of the predetermined dividing line 11 at each of two positions that are spaced from each other in the widthwise direction of the predetermined dividing line 11. Accordingly, as shown in FIG. 13B, two (2) first processing grooves 32 are formed at the two positions irradiated with the laser beam L, leaving the end portions 30 on the outer sides of the first processing grooves 32, and leaving a central portion 33 on an inner side between the two first processing grooves 32. Optionally, the laser beam L may be split in the Y-axis direction to form two focused spots Sg along the widthwise direction of the predetermined dividing line 11. Furthermore, the number of first processing grooves 32 may be three or more.

In a second processing step shown in FIG. 13B, the control unit 24 sets the spot diameter Rc of the focused spot Sc of the laser beam L to be greater than or equal to the length Ha of the removed TEGs 13 in the widthwise direction of the predetermined dividing line 11. This setting is the same as that in the second processing step (see FIG. 6B) in the first embodiment. Next, the control unit 24 sets the position of the laser emitter 22 such that the end portions 30 on the both sides and the central portion 33 are included in the range of the focused spot Sc in the widthwise direction of the predetermined dividing line 11 and operates the laser emitter 22 to emit the laser beam L at the wafer 10 and sequentially shifts the irradiation position of the laser beam L along the lengthwise direction of the predetermined dividing line 11.

As shown in FIG. 13C, by performing the second processing step described above, both the end portions 30 and the central portion 33 that are included in the range of the focused spot Sc are irradiated with the laser beam L and removed, thereby forming a second processing groove 34, which is wider than the two first processing grooves 32 formed in the first processing step between the chips 12 that are adjacent in the Y-axis direction.

In the second processing step, the central portion 33 is removed along with the end portions 30 while the central portion 33 is substantially distanced from the chips 12 located on the sides of the predetermined dividing line 11. Therefore, it is unlikely that larger burrs due to the removal of the central portion 33 are formed on the chips 12. Moreover, a total volume of the end portions 30 and the central portion 33 is smaller than a volume of the TEGs 13 that existed before the first processing step. Therefore, while the amount of the metal patterns to be removed in the second processing step is small, the volume of the burrs Qc that may be formed on the chips 12 in the second processing step may be reduced.

In other words, as long as the first processing groove is composed of at least an end portion left unremoved from the original structures, the processing sequence to form the first processing groove or the number of the first processing groove(s) in each predetermined dividing line may be selected with a certain degree of freedom.

Embodiments of the present disclosure may not necessarily be limited to the configurations described above or in the modified example but may be modified, substituted, or altered in various ways without departing from the spirit of the technical idea of the present disclosure. Furthermore, if the technical idea of the present disclosure may be realized in a different way due to technological progress or other derived technology, it may be implemented with use of the method. Therefore, the claims cover all embodiments that may be included within the scope of the technical idea of the present disclosure.

As described above, according to the present disclosure, burrs to be generated or adhere to chips when forming a processing groove along a predetermined dividing line may be reduced, and the present disclosure is advantageous in improving productivity of manufacturing chips from a wafer.

What is claimed is:

1. A method for processing a wafer to form a processing groove on the wafer along a predetermined dividing line, on at least a part of which a structure is formed, the method comprising:
forming a first processing groove by removing the structure partly and leaving at least an end portion of the structure unremoved, the end portion including at least one end of the structure in a widthwise direction of the predetermined dividing line; and
forming a second processing groove along the predetermined dividing line by removing the end portion of the structure being left in forming the first processing groove.

2. The method according to claim 1, wherein the first processing groove and the second processing groove are formed by emitting a laser beam at the wafer.

3. The method according to claim 1, wherein a volume of the structure to be removed to form the first processing groove is larger than a volume of the structure to be removed to form the second processing groove.

4. The method according to claim 2, wherein output of the laser beam emitted to form the second processing groove is smaller than output of the laser beam emitted to form the first processing groove.

5. The method according to claim 2,
wherein the first processing groove and the second processing grooves are formed, respectively, by shifting a focused spot of the laser beam sequentially along an extending direction of the predetermined dividing line, and
wherein a distance between centers of adjacent focused spots of the laser beam emitted to form the first processing groove along the extending direction of the predetermined dividing line is smaller than a distance between centers of adjacent focused spots of the laser beam emitted to form the second processing groove along the extending direction of the predetermined dividing line.

6. The method according to claim 1, wherein a proportion of the structure to be left in forming the first processing groove in the widthwise direction of the predetermined dividing line is within a range from 2% to 40%, inclusive, relative to a dimension of the structure in the widthwise direction.

7. A method for manufacturing a plurality of chips by dividing the wafer along at least one of the first processing groove or the second processing groove formed in the method according to claim 1.
